(19) United States
(12) Patent Application Publication
(10) Pub. No.: US 2024/0344772 A1
(43) Pub. Date: Oct. 17, 2024

(54) HEAT SINK APPARATUS

(71) Applicant: Research & Business Foundation Sungkyunkwan University, Suwon-si (KR)

(72) Inventors: Sung-Min KIM, Suwon-si (KR); Hyeong-Geun KIM, Suwon-si (KR); Santhosh SENGUTTUVAN, Suwon-si (KR); Hong-Cheol SHIN, Suwon-si (KR); Won-Woo CHOI, Suwon-si (KR)

(73) Assignee: Research & Business Foundation Sungkyunkwan University, Suwon-si (KR)

(21) Appl. No.: 18/624,485

(22) Filed: Apr. 2, 2024

(30) Foreign Application Priority Data
Apr. 17, 2023 (KR) 10-2023-0050215

(51) Int. Cl. F28D 15/02; F28D 21/00

(52) U.S. Cl. CPC F28D 15/02; F28D 2021/0029

(57) ABSTRACT

The present disclosure relates to a heat sink apparatus including a heating body that receives heat from an external heat source, a supplier that is supported by the heating body and supplies a cooling fluid, and a jet ejection part that is provided in the supplier and injects the cooling fluid supplied by the supplier toward the heating body.

### CROSS-REFERENCE TO RELATED APPLICATION

This application claims priority to and the benefit of Korean Patent Application No. 10-2023-0050215, filed on Apr. 17, 2023, the disclosure of which is incorporated herein by reference in its entirety.

### BACKGROUND

### 1. Field of the Invention

The present disclosure relates to a heat sink apparatus, and more particularly, to a heat sink apparatus using a combination of a multi-channel cooling method and a impingement cooling method.

### 2. Discussion of Related Art

Generally, as electronic components are developed to have high integration, high density, and high output, heat should be dissipated through heat sinks having excellent heat dissipating effect to ensure smooth and efficient operations of functions of electronic products.

A plurality of multi-channel cooling systems that allow a cooling fluid to flow in a plurality of flow paths and induce heat exchange between the cooling fluid and a heat source are applied to the heat sinks according to the related art. However, in the multi-channel cooling system, as a temperature of the cooling fluid continuously increases while the cooling fluid flows along a channel, a temperature at an outlet of the channel becomes higher than a temperature at an inlet thereof, and thus cooling performance decreases toward a downstream side. Further, in the multi-channel cooling system, vapor bubbles are generated during a process in which a phase of the cooling fluid is changed and stacked on a heating surface, and as a result, a vapor film is generated. The vapor film serves as a factor that reduces heat exchange efficiency by blocking access of the cooling fluid in liquid phase to the heating surface.

As a manner for compensating for disadvantages of the multi-channel cooling system, there is an impingement cooling system that allows the cooling fluid to directly collide with the heating surface and thus prevents formation of the vapor film on the heating surface. However, the impingement cooling system requires a large amount of cooling fluid, has many components such as jet ejection equipment for injecting the cooling fluid in liquid phase, is complex, and requires a large size of a basic space.

The background technology of the present disclosure is disclosed in Korean Patent Application Publication No. 10-2023-0001004 (registered on Jan. 3, 2023, Title of the Invention: Micro-Channel Heat sink and Method of Manufacturing The Same).

### SUMMARY OF THE INVENTION

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Various embodiments are directed to a heat sink apparatus using a combination of a multi-channel cooling method and a impingement cooling method to improve heat exchange performance.

According to an aspect of the present disclosure, a heat sink apparatus includes a heating body that receives heat from an external heat source, a supplier that is supported by the heating body and supplies a cooling fluid, and a jet ejection part that is provided in the supplier and injects the cooling fluid supplied by the supplier toward the heating body.

The heating body may include a first heating body, a second heating body extending from the first heating body and configured to support the supplier, and a heat exchange channel that is disposed adjacent to the second heating body and guides flow of the cooling fluid injected from the jet ejection part.

The second heating body and the heat exchange channel may be provided as a plurality of second heating bodies and a plurality of heat exchange channels, and the second heating bodies and the heat exchange channels may be arranged alternately on the first heating body.

The supplier may include a supply body spaced apart from the second heating body, a support member extending from the supply body and configured to support the supply body with respect to the second heating body, and a supply channel extending from the support body and disposed inside the heat exchange channel.

A longitudinal direction of the supply channel may be parallel to a longitudinal direction of the heat exchange channel.

A cross-sectional area of the supply channel may be smaller than a cross-sectional area of the heat exchange channel.

The support member may include a pair of first support members arranged on both sides of the supply body; and a second support member disposed between the pair of first support members.

A length of the second support member may be smaller than a length of the supply channel.

The supplier may further include a gas collector disposed adjacent to the supply channel and connected to the heat exchange channel.

The gas collector may be connected to an upper surface of the heat exchange channel.

The jet ejection part may include a jet hole that is formed to pass through the supply channel and injects the cooling fluid to the heat exchange channel.

The jet hole may include a first jet hole that is disposed to face the first heating body and allows the cooling fluid flowing into the supply channel to collide with the first heating body, and a second jet hole that is disposed to face the second heating body and allows the cooling fluid flowing into the supply channel to collide with the second heating body.

The second jet hole may pass through the supply channel in a direction inclined at a set angle with respect to a direction perpendicular to the second heating body.

The heat sink apparatus may further include an inlet through which the cooling fluid flows into the supplier, and an outlet through which the cooling fluid is discharged from the heating body.

The inlet may include an inlet body extending from the supply body and disposed to face one end of the heat exchange channel, and an inlet hole formed to pass through the inlet body and connected to one end of the supply channel, and the outlet may include a first outlet hole spaced apart from the inlet hole and connected to the other end of the heat exchange channel.

The outlet may further include a second outlet hole formed to pass through the supply body and connected to an upper surface of the heat exchange channel.

The heat sink apparatus may further include a filter that is disposed to face the second outlet hole and allows a cooling fluid in vapor phase to be selectively transmitted.

The supplier may be made of a material having lower thermal conductivity than the heating body.

The supplier may be made of an insulating material.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a schematic perspective view illustrating a configuration of a heat sink apparatus according to a first embodiment of the present disclosure;

FIG. 2 is a perspective view illustrating the configuration of the heat sink apparatus according to the first embodiment of the present disclosure in a different viewpoint from that of FIG. 1;

FIG. 3 is a schematic exploded perspective view illustrating the configuration of the heat sink apparatus according to the first embodiment of the present disclosure;

FIG. 4 is an exploded perspective view illustrating the configuration of the heat sink apparatus according to the first embodiment of the present disclosure in a different viewpoint from that of FIG. 3;

FIG. 5 is a schematic cross-sectional perspective view illustrating the configuration of the heat sink apparatus according to the first embodiment of the present disclosure;

FIG. 6 is a schematic front cross-sectional view illustrating the configuration of the heat sink apparatus according to the first embodiment of the present disclosure;

FIG. 7 is a schematic cross-sectional plan view illustrating the configuration of the heat sink apparatus according to the first embodiment of the present disclosure;

FIGS. 8 to 10 are schematic views illustrating a process of operating the heat sink apparatus according to the first embodiment of the present disclosure;

FIG. 11 is a schematic front cross-sectional view illustrating a configuration of a jet ejection part according to a second embodiment of the present disclosure;

FIG. 12 is a schematic perspective view illustrating a configuration of a heat sink apparatus according to a third embodiment of the present disclosure;

FIG. 13 is a schematic exploded perspective view illustrating the configuration of the heat sink apparatus according to the third embodiment of the present disclosure;

FIG. 14 is a schematic front cross-sectional view illustrating the configuration of the heat sink apparatus according to the third embodiment of the present disclosure;

FIGS. 15 and 16 are schematic views illustrating a process of operating the heat sink apparatus according to the third embodiment of the present disclosure;

FIG. 17 is a schematic perspective view illustrating a configuration of a heat sink apparatus according to a fourth embodiment of the present disclosure;

FIG. 18 is a schematic exploded perspective view illustrating the configuration of the heat sink apparatus according to the fourth embodiment of the present disclosure;

FIG. 19 is a schematic front cross-sectional view illustrating the configuration of the heat sink apparatus according to the fourth embodiment of the present disclosure; and

FIGS. 20 and 21 are schematic views illustrating a process of operating the heat sink apparatus according to the fourth embodiment of the present the present disclosure.

### DETAILED DESCRIPTION OF EXEMPLARY EMBODIMENTS

Hereinafter, a heat sink apparatus according to embodiments of the present disclosure will be described with reference to the accompanying drawings.

In this process, the thickness of lines or the size of components illustrated in the drawings may be exaggerated for clarity and convenience of description. Further, terms described below are terms defined in consideration of functions in the present disclosure and may change according to the intention or custom of a user or an operator. Therefore, definitions of these terms should be made based on the contents throughout the present specification.

Further, in the specification, a state in which a first part is “connected” to a second part may include a case in which the first part is “directly connected” to the second part as well as a case in which the first part is “indirectly connected” to the second part with a third part interposed therebetween. In the specification, a state in which a first component “includes (or is provided with)” a second component means that a third part is not excluded but further “included (or provided)” therein unless otherwise stated.

Further, the same reference numerals may refer to the same components throughout the specification. Even when the same or similar reference numerals are not mentioned or described in a specific drawing, the numerals may be described based on other drawings. Further, even when there is a part that is not indicated by a reference numeral in a specific drawing, this part may be described based on other drawings. Further, the number, the shape, the size, and the relative difference in size of detailed components included in the drawings of the present disclosure are set for convenience of understanding, do not limit the embodiments, and may be implemented in various forms.

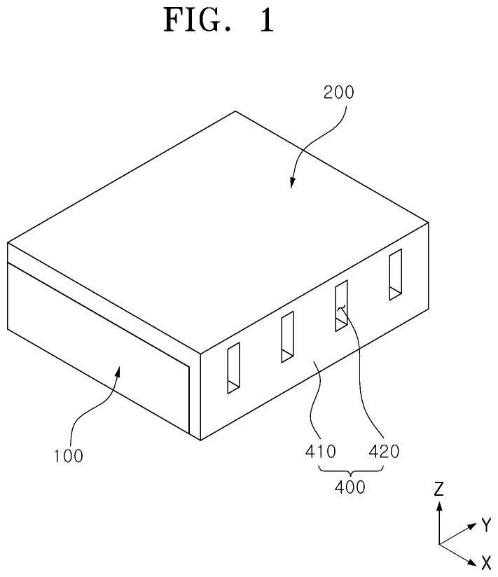

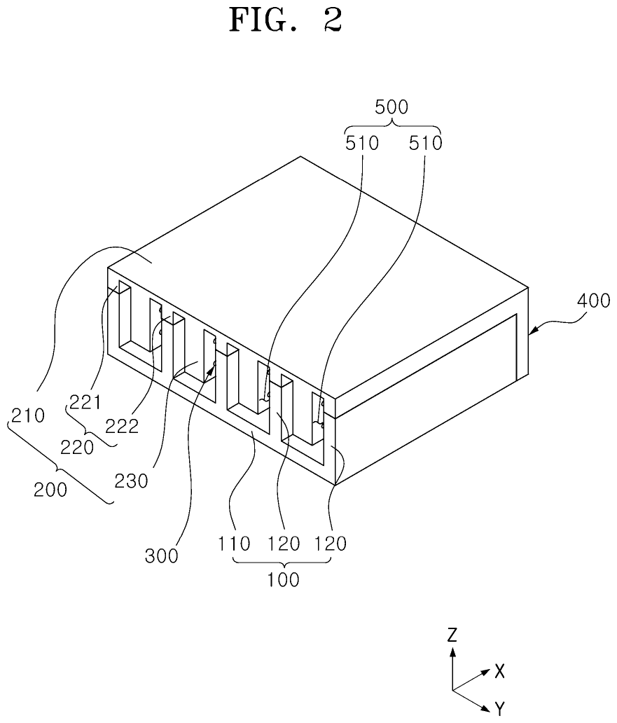

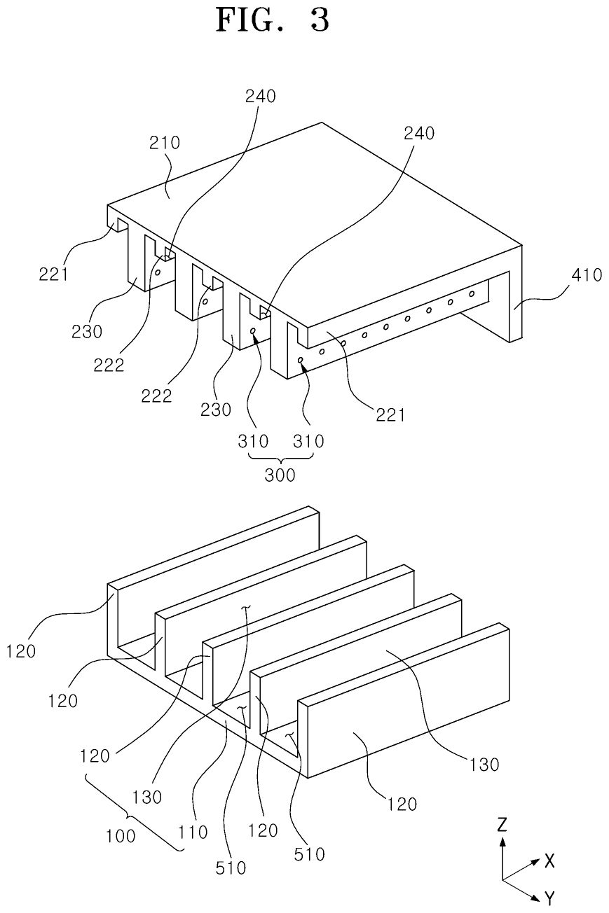

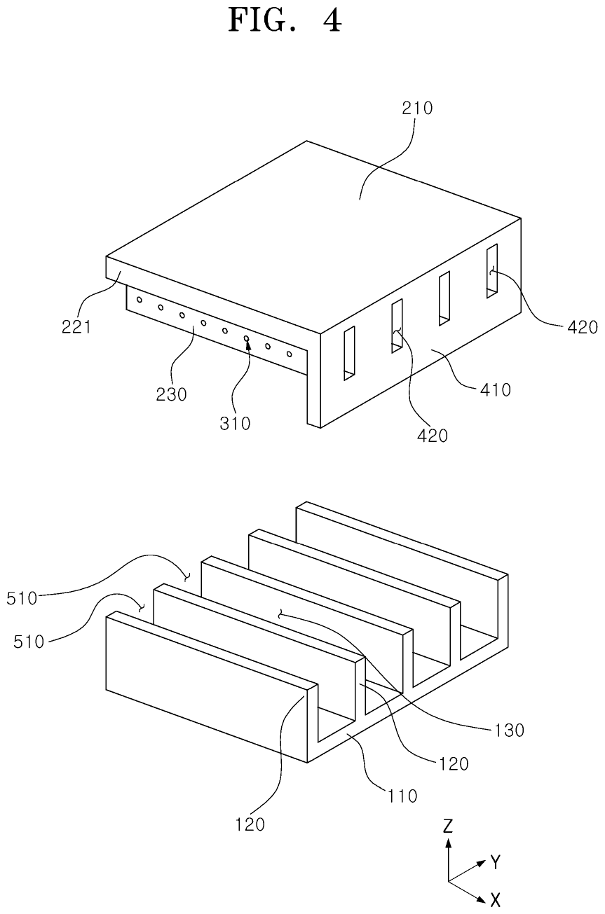

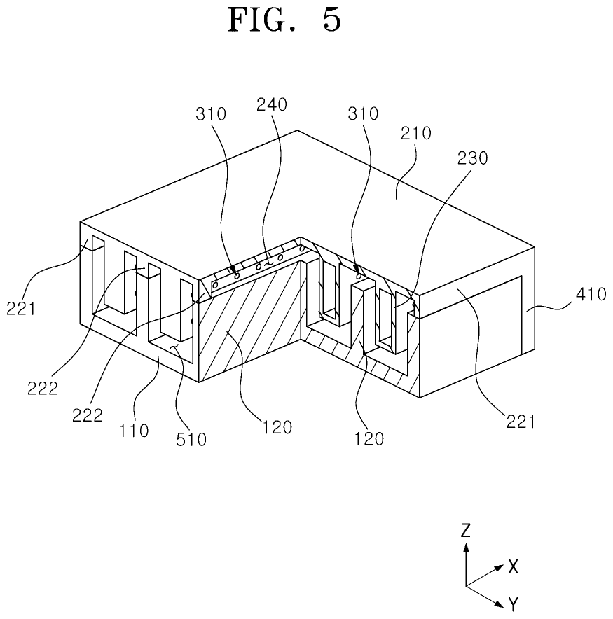

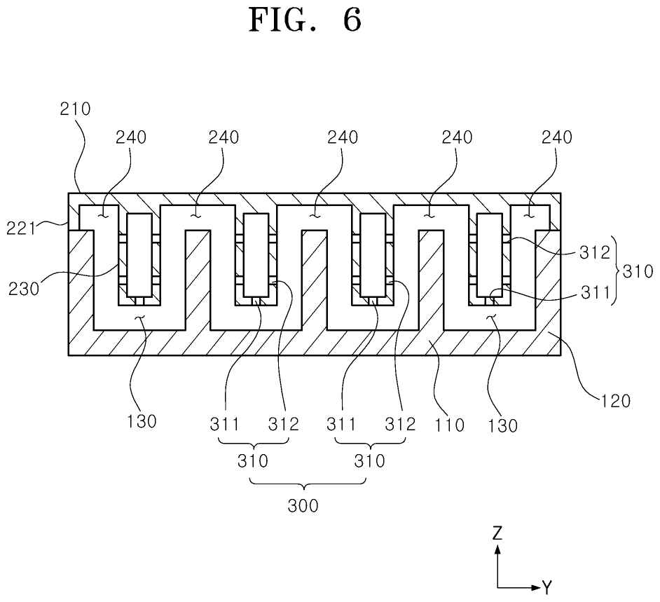

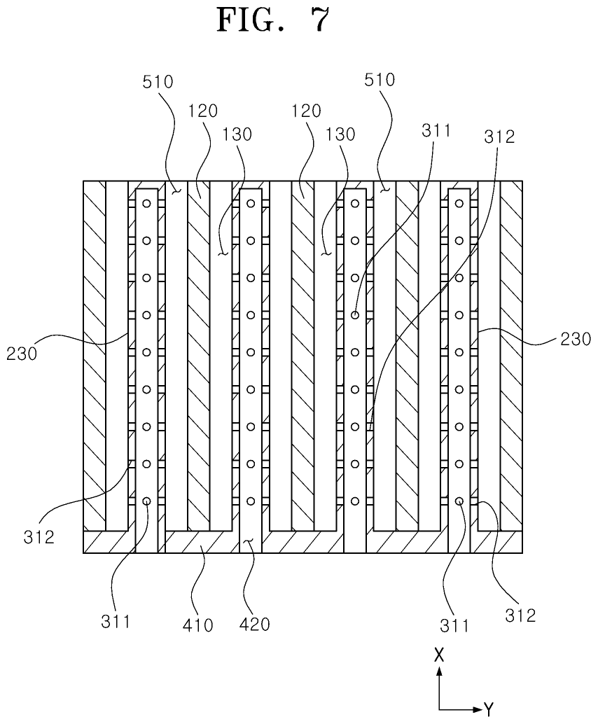

FIG. 1 is a schematic perspective view illustrating a configuration of a heat sink apparatus according to a first embodiment of the present disclosure, FIG. 2 is a perspective view illustrating the configuration of the heat sink apparatus according to the first embodiment of the present disclosure in a different viewpoint from that of FIG. 1, FIG. 3 is a schematic exploded perspective view illustrating the configuration of the heat sink apparatus according to the first embodiment of the present disclosure, FIG. 4 is an exploded perspective view illustrating the configuration of the heat sink apparatus according to the first embodiment of the present disclosure in a different viewpoint from that of FIG. 3, FIG. 5 is a schematic cross-sectional perspective view illustrating the configuration of the heat sink apparatus according to the first embodiment of the present disclosure, FIG. 6 is a schematic front cross-sectional view illustrating the configuration of the heat sink apparatus according to the first embodiment of the present disclosure, and FIG. 7 is a schematic cross-sectional plan view illustrating the configuration of the heat sink apparatus according to the first embodiment of the present disclosure.

Referring to FIGS. 1 to 7, the heat sink apparatus according to the present embodiment may include a heating body 100, a supplier 200, and a jet ejection part 300.

The heating body 100 receives heat from an external heat source. Here, the external heat source may be exemplified as any of various types of devices that continuously generate heat in a process of operating circuit boards, various types of electronic equipment, and the like. The heating body 100 may be made of a metallic material having high thermal conductivity, such as aluminum or copper, to effectively receive heat generated by the external heat source.

The heating body 100 according to the present embodiment may include a first heating body 110, a second heating body 120, and a heat exchange channel 130.

The first heating body 110 forms an exterior of one side of the heating body 100 and is in contact with the external heat source. The first heating body 110 according to the present embodiment may be formed to have a substantially flat plate shape. A lower surface of the first heating body 110 may be in direct contact with the external heat source and heated by receiving the heat generated by the heat source. In this case, the lower surface of the first heating body 110 may be integrally coupled to a surface of the heat source by welding or the like, and the lower surface of the first heating body 110 may be detachably coupled to the surface of the heat source by bolting, fitting, or the like. A detailed shape, a detailed area, and the like of the first heating body 110 are not limited to those illustrated in FIGS. 4 and 5, and a design of the first heating body 110 may be variously changed according to the shape, the size, and the like of the external heat source.

The second heating body 120 forms an exterior of the other side of the heating body 100 and supports the supplier 200, which will be described below. The second heating body 120 according to the present embodiment may be formed to have a shape of a plate extending vertically upward from an upper surface of the first heating body 110. A longitudinal direction of the second heating body 120 may be parallel to a longitudinal direction of the first heating body 110, that is, an X-axis direction, based on FIGS. 1 to 4. A width of the second heating body 120 parallel to a Y-axis direction based on FIGS. 1 to 4 may be smaller than a width of the first heating body 110.

The second heating body 120 may be provided as a plurality of second heating bodies 120. The plurality of second heating bodies 120 may be spaced apart from each other in a width direction of the first heating body 110, that is, in a direction parallel to the Y-axis direction, based on FIGS. 1 to 4. Adjacent second heating bodies 120 may be arranged to face each other in parallel. Among the plurality of second heating bodies 120, a pair of second heating bodies 120 arranged on the outermost side may be arranged at upper edges of the first heating body 110.

The heat exchange channel 130 is disposed adjacent to the second heating body 120 and guides flow of a cooling fluid injected from the jet ejection part 300 which will be described below. That is, the heat exchange channel 130 may function as a component that heat-exchanges the cooling fluid injected from the jet ejection part 300 with the first heating body 110 and the second heating body 120 and guides flow of the cooling fluid that is completely heat-exchanged with the first heating body 110 and the second heating body 120.

The heat exchange channel 130 according to the present embodiment may be exemplified as an empty space formed between the adjacent second heating bodies 120. The second heating body 120 and the heat exchange channel 130 may be arranged alternately in the width direction of the first heating body 110 on the first heating body 110, that is, in a direction parallel to the Y-axis direction, based on FIGS. 1 to 4. When three or more second heating bodies 120 are formed, the heat exchange channel 130 may be provided as a plurality of heat exchange channels 130 and may be individually arranged between the adjacent second heating bodies 120. A longitudinal direction of the heat exchange channel 130 may be in parallel to the longitudinal direction of the second heating body 120. Both longitudinal ends and an upper surface of the heat exchange channel 130 may be formed to be open.

The supplier 200 is supported by the heating body 100 and supplies a cooling fluid. That is, the supplier 200 may function as a component that supplies the cooling fluid for cooling the heating body 100 into the heat exchange channel 130. Here, the cooling fluid may be exemplified by any of various types of heat exchange media, such as water and ammonia, by which the heating body 100 may be cooled through the heat exchange with the heating body 100.

The supplier 200 may supply the cooling fluid in a liquid state to the heating body 100. In this case, the supplier 200 may be formed of a material having lower thermal conductivity than the heating body 100. In more detail, the supplier 200 may be formed of an insulating material, such as synthetic resin or ceramic, which has insulating properties. Accordingly, in a process of supplying the cooling fluid to the heating body 100, the supplier 200 may prevent an increase in the temperature and a phase change of the cooling fluid through the heat exchange with the heating body 100 or the external heat source and may further improve cooling efficiency in the heat exchange channel 130.

The supplier 200 according to the present embodiment may include a supply body 210, a support part 220, and a supply channel 230.

The supply body 210 forms an exterior of one side of the supplier 200 and is spaced apart from the second heating body 120. The supply body 210 according to the present embodiment may be formed to have a shape of a substantially flat plate. The supply body 210 may be disposed on the heating body 100. In more detail, a lower surface of the supply body 210 may be spaced a predetermined distance from the upper surfaces of the second heating body 120 and the heat exchange channel 130. The supply body 210 may be disposed to face the first heating body 110 in parallel. An area of the supply body 210 may be formed to correspond to an area of the first heating body 110.

The support part 220 extends from the supply body 210 and supports the supply body 210 with respect to the second heating body 120.

The support part 220 according to the present embodiment may include a first support member 221 and a second support member 222.

The first support member 221 may be formed to have a shape of a rod extending vertically downward from the lower surface of the supply body 210. A longitudinal direction of the first support member 221 may be parallel to a longitudinal direction of the supply body 210, that is, the X-axis direction, based on FIGS. 1 to 4. In this case, the first support member 221 may be arranged parallel to the second heating body 120.

The first support member 221 may be provided in pair. The pair of first support members 221 may be spaced apart from each other in a width direction of the supply body 210, that is, in a direction parallel to the Y-axis direction, based on FIGS. 1 to 4. The pair of first support members 221 may be arranged at edges of the lower surface of the supply body 210 in the width direction.

Lower surfaces of the pair of first support members 221 may be in contact with upper surfaces of the pair of second heating bodies 120 arranged at edges of the upper surface of the first heating body 110 in the width direction among the plurality of second heating bodies 120. Accordingly, the pair of first support members 221 may support the supply body 210 with respect to the second heating body 120, and at the same time, may prevent the cooling fluid flowing into the heat exchange channel 130 from flowing outward in the width direction of the supply body 210.

The second support member 222 may be formed to have a shape of a rod extending vertically downward from the lower surface of the supply body 210. The second support member 222 may be disposed between the pair of first support members 221.

A longitudinal direction of the second support member 222 may be parallel to the longitudinal direction of the supply body 210, that is, the X-axis direction, based on FIGS. 1 to 4. A length of the second support member 222 may be smaller than a length of the first support member 221, as illustrated in FIG. 5. The second support member 222 may be disposed at an end of the supply body 210 in the longitudinal direction. Accordingly, the second support member 222 may prevent an increase in the temperature of the cooling fluid, which is caused by the heat exchange with the second heating body 120, due to a decrease in a contact area with the second heating body 120.

The second support member 222 may be provided as a plurality of second support members 222. The plurality of second support members 222 may be spaced apart from each other in the width direction of the supply body 210. A lower surface of the second support member 222 may be individually in contact with the upper surface of the remaining second heating body 120 except for the second heating body 120 in contact with the first support member 221 among the plurality of second heating bodies 120. The detailed number of second support members 222 may be changed in any of various designs depending on the number of second heating bodies 120 and the like.

The supply channel extends from the supply body 210 and is disposed inside the heat exchange channel 130. The supply channel 230 may function as a component that guides the flow of the cooling fluid supplied from an external unit to an interior of the heat exchange channel 130. The supply channel 230 according to the present embodiment may be formed to have a hollow channel shape and may extend vertically downward from the lower surface of the supply body 210. The supply channel 230 may be disposed inside the heat exchange channel 130. A lower surface and both side surfaces of the supply channel 230 may be arranged to face the first heating body 110 and the second heating body 120.

A longitudinal direction of the supply channel 230 may be parallel to the longitudinal direction of the heat exchange channel 130. Accordingly, the supply channel 230 may supply the cooling fluid throughout an entire length of the heat exchange channel 130. A cross-sectional area of the supply channel 230 may be smaller than a cross-sectional area of the heat exchange channel 130. In more detail, the cross-sectional area of the supply channel 230 may be smaller than a cross-sectional area excluding the cross-sectional area of the supply channel 230 from the entire cross-sectional area of the heat exchange channel 130. Accordingly, the supply channel 230 may expand a space in the heat exchange channel 130 for movement of a cooling fluid in vapor phase that is phase-changed due to the heat exchange with the heating body 100, thereby improving stability of boiling flow and delaying occurrence of a critical heat flux. A cross-sectional shape of the supply channel 230 is not limited to a quadrangular shape illustrated in FIG. 6 and may be changed to any of various shapes such as a circular shape, an oval shape, a trapezoidal shape, and a polygonal shape.

The supply channel 230 may be provided as a plurality of supply channels 230. The plurality of supply channels 230 may be spaced apart from each other in the width direction of the supply body 210. The supply channels 230 may be individually arranged inside different heat exchange channels 130.

The supplier 200 according to the present embodiment may further include a gas collector 240.

The gas collector 240 is disposed adjacent to the supply channel 230 and connected to the heat exchange channel 130. The gas collector 240 may function as a component that collects, in a space separate from the heat exchange channel 130, the cooling fluid in vapor phase separated from a cooling fluid in liquid phase due to gravity and a density difference inside the heat exchange channel 130. Accordingly, the gas collector 240 may decrease dryness of the gas inside the heat exchange channel 130 in a process of cooling the heating body 100, thereby further improving cooling efficiency of the heating body 100.

The gas collector 240 according to the present embodiment may be exemplified as empty spaces formed between adjacent supply channels 230 and between the supply channel 230 and the first support member 221. A longitudinal direction of the gas collector 240 may be parallel to the longitudinal direction of the supply channel 230. A lower surface of the gas collector 240 may be connected to the upper surface of the heat exchange channel 130. Accordingly, the gas collector 240 may guide the cooling fluid in vapor phase, which moves to an upper side of the heat exchange channel 130 due to the density different even without a separate external force, to the inside thereof.

The jet ejection part 300 is provided in the supplier 200 and injects the cooling fluid supplied by the supplier 200 toward the heating body 100. That is, the jet ejection part 300 may function as a component that allows the cooling fluid supplied by the supplier 200 to directly collide with surfaces of the first heating body 110 and the second heating body 120, thereby implementing an jet impingement cooling effect on the heating body 100. Accordingly, the jet ejection part 300 may prevent the cooling fluid in vapor phase that is phase-changed inside the heat exchange channel 130 due to the heat exchange with the heating body 100 from forming a vapor film on the surfaces of the first heating body 110 and the second heating body 120, thereby delaying the occurrence of the critical heat flux and improving the cooling efficiency of the heating body 100.

The jet ejection part 300 according to the present embodiment may include a jet hole 310.

The jet hole 310 is formed to pass through the supply channel 230 and injects the cooling fluid flowing along the supply channel 230 to the heat exchange channel 130. The jet hole 310 may be formed individually with respect to each of the supply channels 230.

The jet hole 310 according to the present embodiment may include a first jet hole 311 and a second jet hole 312.

The first jet hole 311 is disposed to face the first heating body 110 and allows the cooling fluid flowing into the supply channel 230 to collide with the first heating body 110. The first jet hole 311 according to the present embodiment may be formed to have a shape of a hole vertically passing through a lower surface of the supply channel 230 in a Z-axis direction based on FIGS. 1 to 4. Both ends of the first jet hole 311 may be connected to an internal space of the supply channel 230 and the heat exchange channel 130. The first jet hole 311 may inject the cooling fluid in liquid phase flowing inside the supply channel 230 into the heat exchange channel 130, thereby allowing the cooling fluid to collide with the surface of the first heating body 110.

The first jet hole 311 may be provided as a plurality of first jet holes 311. The plurality of first jet holes 311 may be spaced a predetermined interval from each other in the longitudinal direction of the supply channel 230. The cross-sectional shape, the number, the interval, or the like of the first jet holes 311 may be changed in any of various designs according to the shape, the size, or the like of the supply channel 230.

The second jet hole 312 is disposed to face the second heating body 120 and allows the cooling fluid flowing into the supply channel 230 to collide with the second heating body 120. The second jet hole 312 according to the present embodiment may be formed to have a shape of a hole vertically passing through side surfaces of the supply channel 230 in the Y-axis direction based on FIGS. 1 to 4. Both ends of the second jet hole 312 may be connected to the internal space of the supply channel 230 and the heat exchange channel 130. The second jet hole 312 may inject the cooling fluid in liquid phase flowing inside the supply channel 230 into the heat exchange channel 130, thereby allowing the cooling fluid to collide with the surface of the second heating body 120.

The second jet hole 312 may be provided as a plurality of second jet holes 312. The plurality of second jet holes 312 may be spaced a predetermined interval from each other in the longitudinal direction of the supply channel 230. The plurality of second jet holes 312 may be symmetrically arranged on both side surfaces of the supply channel 230. The cross-sectional shape, the number, the interval, or the like of the plurality of second jet holes 312 may be changed in any of various designs according to the shape, the size, or the like of the supply channel 230.

The heat sink apparatus according to the present embodiment may further include an inlet 400 and an outlet 500.

The inlet 400 allows the cooling fluid in liquid phase supplied from the external unit to flow into the supplier 200.

The inlet 400 according to the present embodiment may include an inlet body 410 and an inlet hole 420.

The inlet body 410 extends from the supply body 210 and is disposed to face one ends of the heat exchange channel 130 and the supply channel 230. The inlet body 410 according to the present embodiment may be formed to have a shape of a plate extending vertically downward from the lower surface of the supply body 210 in the Z-axis direction based on FIGS. 1 to 4. An inner surface of the inlet body 410 may be disposed to face one ends of the heat exchange channel 130 and the supply channel 230 in a direction parallel to the X-axis direction based on FIGS. 1 to 4. Accordingly, the inlet body 410 may prevent the cooling fluid supplied from the external unit from directly flowing into the heat exchange channel 130. A material of the inlet body 410 may be the same as that of the supplier 200.

The inlet hole 420 is formed to pass through the inlet body 410 and connected to one end of the supply channel 230. The inlet hole 420 according to the present embodiment may be formed to have a shape of a hole vertically passing through the inlet body 410 in the longitudinal direction of the supply channel 230. Both sides of the inlet hole 420 may be connected to an internal space of the inlet body 410 and an internal space of the supply channel 230. In this case, the other end of the supply channel, that is, an end at a side opposite to a side connected to the inlet hole 420, may be closed. The inlet hole 420 may be connected to an external cooling fluid supply means (not illustrated) by means of a hose, a pipe, or the like. The inlet hole 420 may be provided as a plurality of inlet holes 420. The plurality of inlet holes 420 may be individually connected to one ends of the plurality of supply channels 230.

The outlet 500 discharges, from the heating body 100, the cooling fluid that is completely heat-exchanged with the heating body 100 after the cooling fluid is injected to the heating body 100 through the jet ejection part 300.

The outlet 500 according to the present embodiment may include a first outlet hole 510.

The first outlet hole 510 is spaced apart from the inlet hole 420 and connected to the other end of the heat exchange channel 130. The first outlet hole 510 according to the present embodiment may be formed in a shape of a hole through which an end disposed at a side opposite to an end disposed to face the inlet body 410 among both ends of the heat exchange channel 130 and an external space of the heating body 100 connected to each other. The first outlet hole 510 may be provided as a plurality of first outlet holes 510. The plurality of first outlet holes 510 may be individually connected to the other ends of the plurality of heat exchange channels 130.

Hereinafter, a process of operating the heat sink apparatus according to the first embodiment of the present disclosure will be described.

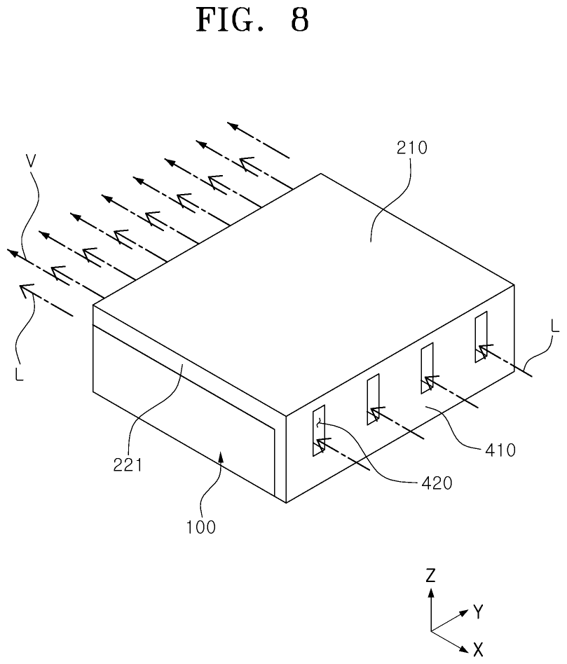

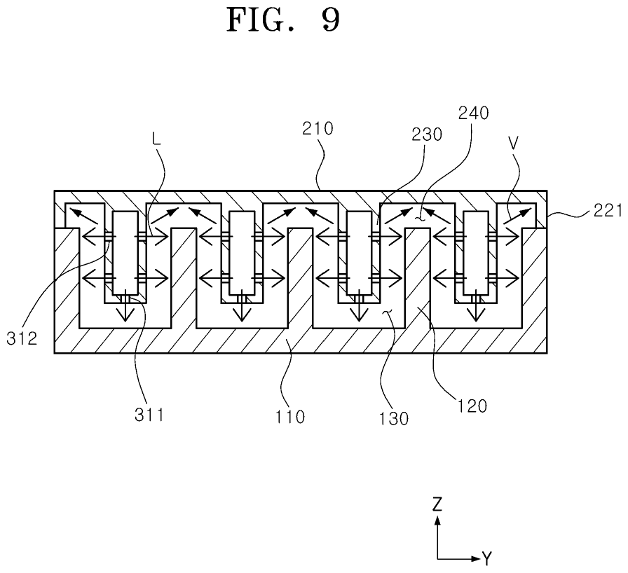

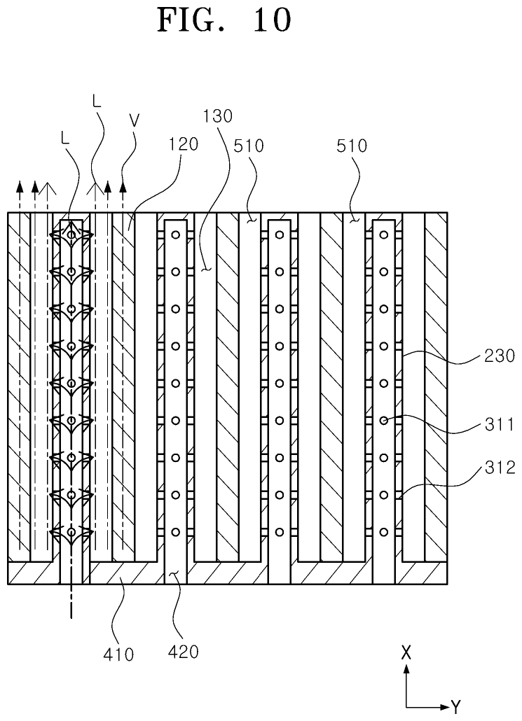

FIGS. 8 to 10 are schematic views illustrating a process of operating the heat sink apparatus according to the first embodiment of the present disclosure.

Referring to FIGS. 8 to 10, a temperature of the heating body 100 increases as heat is received from the external heat source.

A cooling fluid in liquid phase L supplied from the external unit is transferred into the supply channel 230 through the inlet hole 420.

The cooling fluid in liquid phase L transferred into the supply channel 230 flows in the longitudinal direction of the supply channel 230.

In this process, the supplier 200 is made of an insulating material, and the second support member 222 is in contact with only a partial area of the second heating body 120. Thus, the heat of the heating body 100 is not transferred to the supplier 200, and the cooling fluid in liquid phase L flowing inside the supply channel 230 may be uniformly supplied along the entire heat exchange channel 130 in the longitudinal direction without phase change while an initial temperature is maintained.

Thereafter, the jet hole 310 injects the cooling fluid in liquid phase L flowing inside the supply channel 230 to the heat exchange channel 130.

In more detail, the first jet hole 311 injects the cooling fluid in liquid phase L toward the first heating body 110, and the second jet hole 312 injects the cooling fluid in liquid phase L toward the second heating body 120.

The cooling fluid in liquid phase injected through the first jet hole 311 and the second jet hole 312 is heat-exchanged with the first heating body 110 and the second heating body 120 and cools the first heating body 110 and the second heating body 120 while flowing inside the heat exchange channel 130.

In this process, a portion of the cooling fluid in liquid phase L is phase-changed into a cooling fluid in vapor phase V by the heat transferred from the first heating body 110 and the second heating body 120 in a liquid state.

Further, the cooling fluid in liquid phase L injected through the first jet hole 311 and the second jet hole 312 may directly collide with the surfaces of the first heating body 110 and the second heating body 120 due to its own flowing force, and thus, may prevent the cooling fluid in vapor phase V from forming a vapor film on the surfaces of the first heating body 110 and the second heating body 120 due to the jet impingement cooling effect.

The cooling fluid in vapor phase V generated inside the heat exchange channel 130 moves to an upper side of the heat exchange channel 130 due to a density difference between the cooling fluid in liquid phase L and the cooling fluid in vapor phase V, and a portion of the cooling fluid in vapor phase V flows into the gas collector 240. Accordingly, the dryness of the gas inside the heat exchange channel 130 decreases, and thus, stability of the flow of the cooling fluid may be further improved.

Thereafter, the cooling fluid in liquid phase L and the cooling fluid in vapor phase V flow in the longitudinal direction of the heat exchange channel 130 and are discharged to the outside of the heating body 100 through the first outlet hole 510.

Hereinafter, a heat sink apparatus according to a second embodiment of the present disclosure will be described.

The heat sink apparatus according to the second embodiment of the present disclosure may differ from the heat sink apparatus according to the first embodiment of the present disclosure only in the detailed configuration of the jet ejection part 300. Accordingly, in describing the configuration of the heat sink apparatus according to the second embodiment of the present disclosure, only the detailed configuration of the jet ejection part 300, which is different from that of the heat sink apparatus according to the first embodiment of the present disclosure, will be described.

The descriptions of the heating body 100, the supplier 200, the remaining configuration of the jet ejection part 300, the inlet 400, and the outlet 500 according to the first embodiment of the present disclosure may be applied to the heating body 100, the supplier 200, the remaining configuration of the jet ejection part 300, the inlet 400, and the outlet 500 of the heat sink apparatus according to the second embodiment of the present disclosure without change.

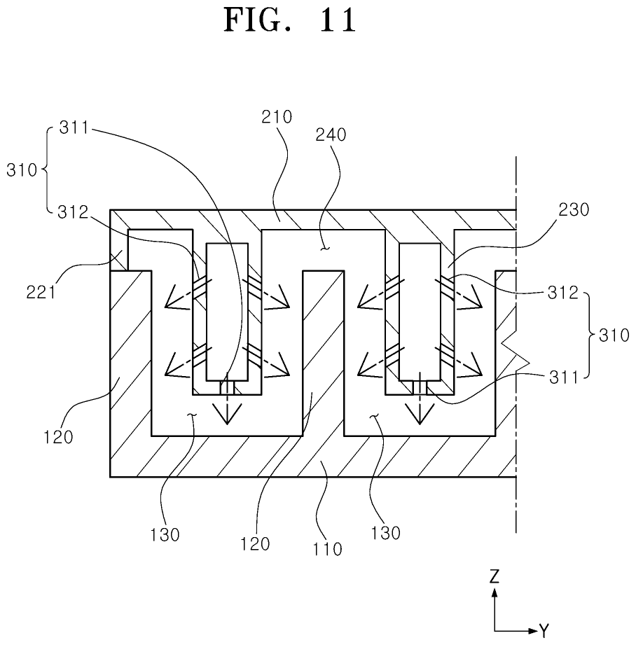

FIG. 11 is a schematic front cross-sectional view illustrating a configuration of a jet ejection part according to a second embodiment of the present disclosure.

Referring to FIG. 11, the second jet hole 312 according to the present embodiment may be formed to pass through the supply channel 230 in a direction inclined at a set angle with respect to a direction perpendicular to the second heating body 120. That is, a longitudinal direction of the second jet hole 312 may be inclined at the set angle with respect to a width direction of the heat exchange channel 130, that is, in the Y-axis direction, based on FIG. 11. Accordingly, the second jet hole 312 intensively injects the cooling fluid to an area having a relatively high temperature distribution among the entire area of the second heating body 120, and thus, various applications to the second heating body 120 having various structures are possible. FIG. 11 illustratively illustrates that the second jet hole 312 is inclined downward in the width direction of the heat exchange channel 130, but the second jet hole 312 is not limited thereto, and may be inclined upward in the width direction of the heat exchange channel 130.

Hereinafter, a heat sink apparatus according to a third embodiment of the present disclosure will be described.

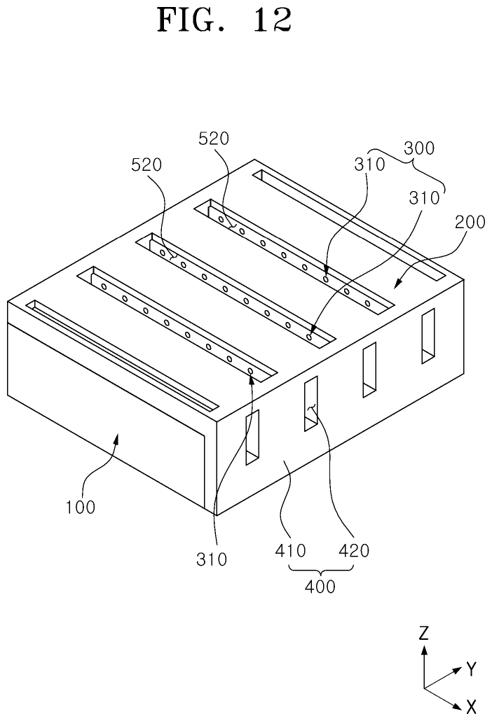

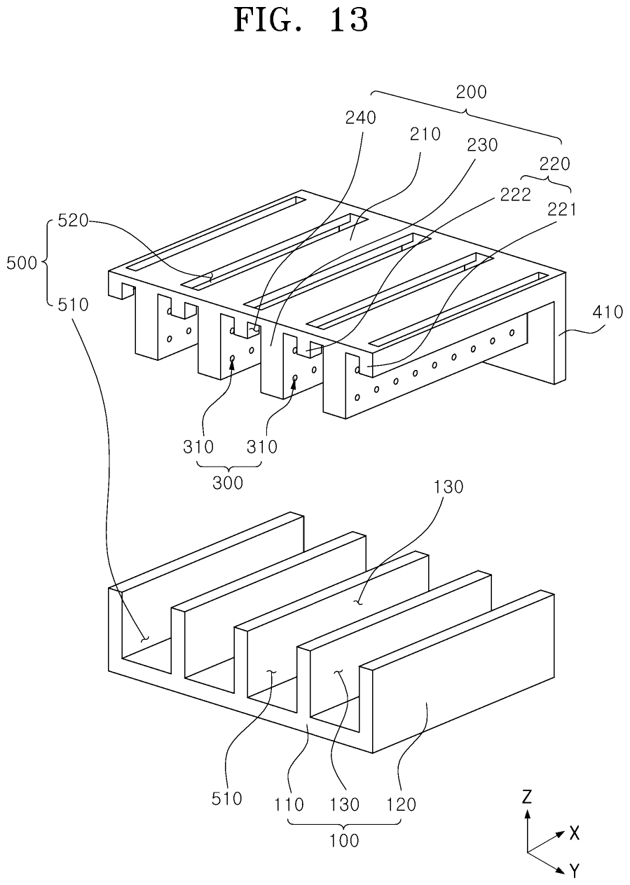

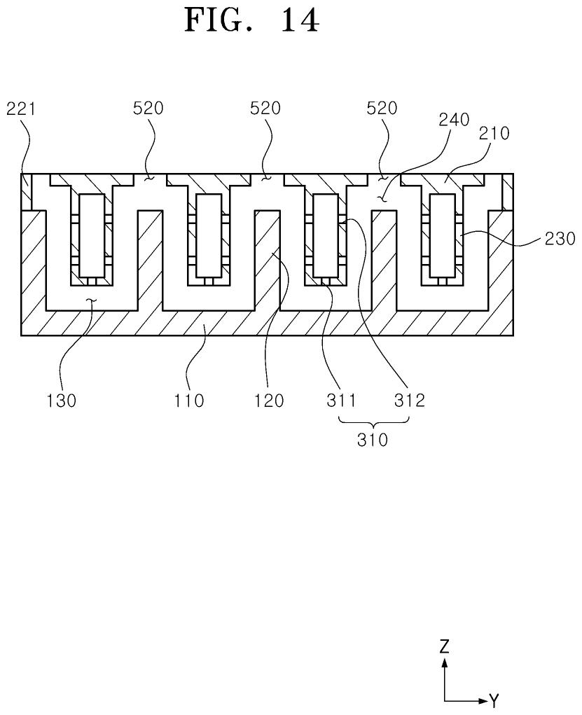

FIG. 12 is a schematic perspective view illustrating a configuration of a heat sink apparatus according to a third embodiment of the present disclosure, FIG. 13 is a schematic exploded perspective view illustrating the configuration of the heat sink apparatus according to the third embodiment of the present disclosure, and FIG. 14 is a schematic front cross-sectional view illustrating the configuration of the heat sink apparatus according to the third embodiment of the present disclosure.

Referring to FIGS. 12 to 14, the heat sink apparatus according to the third embodiment of the present disclosure may include the heating body 100, the supplier 200, the jet ejection part 300, the inlet 400, and the outlet 500.

The heat sink apparatus according to the third embodiment of the present disclosure may differ from the heat sink apparatus according to the first embodiment or the second embodiment of the present disclosure only in the detailed configuration of the outlet 500.

Accordingly, in describing the configuration of the heat sink apparatus according to the third embodiment of the present disclosure, only the detailed configuration of the outlet 500, which is different from that of the heat sink apparatus according to the first embodiment or the second embodiment of the present disclosure, will be described.

The descriptions of the heating body 100, the supplier 200, the jet ejection part 300, the inlet 400, and the remaining configuration of the outlet 500 according to the first embodiment or the second embodiment of the present disclosure may be applied to the heating body 100, the supplier 200, the jet ejection part 300, the inlet 400, and the remaining configuration of the outlet 500 of the heat sink apparatus according to the third embodiment of the present disclosure without change.

The outlet 500 according to the present embodiment may include a second outlet hole 520.

The second outlet hole 520 is formed to pass through the supply body 210 and connected to the upper surface of the heat exchange channel 130. That is, the second outlet hole 520 may function as a component that is separate from the first outlet hole 510 and additionally provides a path through which the cooling fluid in vapor phase generated in the heat exchange channel 130 may be discharged to the outside. Accordingly, the second outlet hole 520 may guide the cooling fluid in vapor phase such that the cooling fluid in vapor phase is discharged more quickly from the interior of the heat exchange channel 130 and may more effectively lower the dryness of the gas inside the heat exchange channel 130.

The second outlet hole 520 according to the present embodiment may be formed to have a shape of a hole vertically passing through an upper surface and a lower surface of the supply body 210 in the Z-axis direction based on FIGS. 12 to 14. An upper surface of the second outlet hole 520 may be connected to an external space of the supply body 210, and the lower surface thereof may be indirectly connected to the upper surface of the heat exchange channel 130 through the gas collector 240. A longitudinal direction of the second outlet hole 520 may be parallel to the longitudinal direction of the heat exchange channel 130, which is parallel to the X-axis direction, based on FIGS. 12 to 14.

The second outlet hole 520 may be provided as a plurality of second outlet holes 520. The plurality of second outlet holes 520 may be spaced apart from each other in the width direction of the heat exchange channel 130, that is, in the Y-axis direction, based on FIGS. 12 to 14. The plurality of second outlet holes 520 may be arranged alternately with the supply channel 230 in the width direction of the heat exchange channel 130.

Hereinafter, a process of operating the heat sink apparatus according to the third embodiment of the present disclosure will be described.

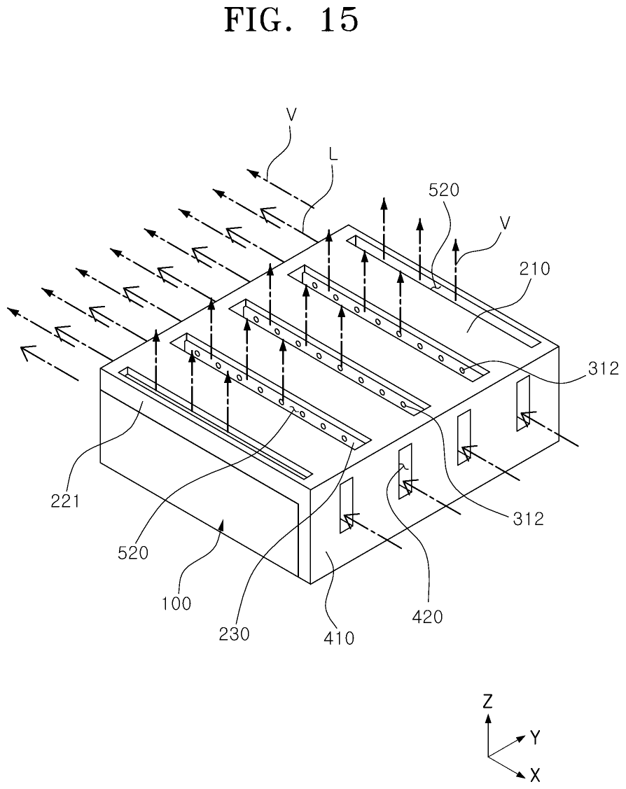

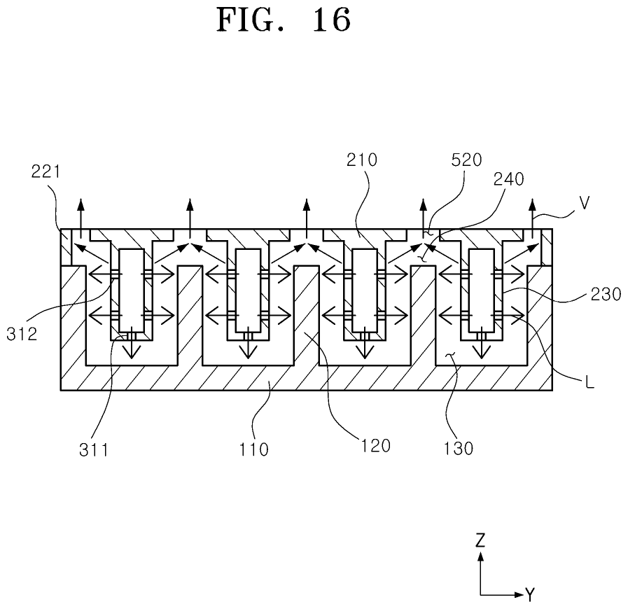

FIGS. 15 and 16 are schematic views illustrating a process of operating the heat sink apparatus according to the third embodiment of the present disclosure.

Referring to FIGS. 15 and 16, the temperature of the heating body 100 increases as the heat is received from the external heat source.

The cooling fluid in liquid phase L supplied from the external unit is transferred into the supply channel 230 through the inlet hole 420.

The cooling fluid in liquid phase L transferred into the supply channel 230 flows in the longitudinal direction of the supply channel 230.

In this process, the supplier 200 is made of an insulating material, and the second support member 222 is in contact with only a partial area of the second heating body 120. Thus, the heat of the heating body 100 is not transferred to the supplier 200, and the cooling fluid in liquid phase L flowing inside the supply channel 230 may be uniformly supplied along the entire heat exchange channel 130 in the longitudinal direction without phase change while an initial temperature is maintained.

Thereafter, the jet hole 310 injects the cooling fluid in liquid phase L flowing inside the supply channel 230 to the heat exchange channel 130.

In more detail, the first jet hole 311 injects the cooling fluid in liquid phase L toward the first heating body 110, and the second jet hole 312 injects the cooling fluid in liquid phase L toward the second heating body 120.

The cooling fluid in liquid phase L injected through the first jet hole 311 and the second jet hole 312 is heat-exchanged with the first heating body 110 and the second heating body 120 and cools the first heating body 110 and the second heating body 120 while flowing inside the heat exchange channel 130.

In this process, a portion of the cooling fluid in liquid phase L is phase-changed into the cooling fluid in vapor phase V by the heat transferred from the first heating body 110 and the second heating body 120 in a liquid state.

Further, the cooling fluid in liquid phase L injected through the first jet hole 311 and the second jet hole 312 may directly collide with the surfaces of the first heating body 110 and the second heating body 120 due to its own flowing force, and thus may prevent the cooling fluid in vapor phase V from forming a vapor film on the surfaces of the first heating body 110 and the second heating body 120 due to the jet impingement cooling effect.

The cooling fluid in vapor phase V generated inside the heat exchange channel 130 moves to the upper side of the heat exchange channel 130 due to the density difference between the cooling fluid in liquid phase L and the cooling fluid in vapor phase V, and a portion of the cooling fluid in vapor phase V flows into the gas collector 240. Accordingly, the dryness of the gas inside the heat exchange channel 130 decreases, and thus the stability of the flow of the cooling fluid may be further improved.

Thereafter, the cooling fluid in liquid phase L and the cooling fluid in vapor phase V flow in the longitudinal direction of the heat exchange channel 130 and are discharged to the outside of the heating body 100 through the first outlet hole 510.

At the same time, the cooling fluid in vapor phase V collected in the gas collector 240 is discharged to the outside of the heating body 100 through the second outlet hole 520. Accordingly, the cooling fluid in vapor phase V may be more quickly removed from the interior of the heat exchange channel 130.

Hereinafter, a heat sink apparatus according to a fourth embodiment of the present disclosure will be described.

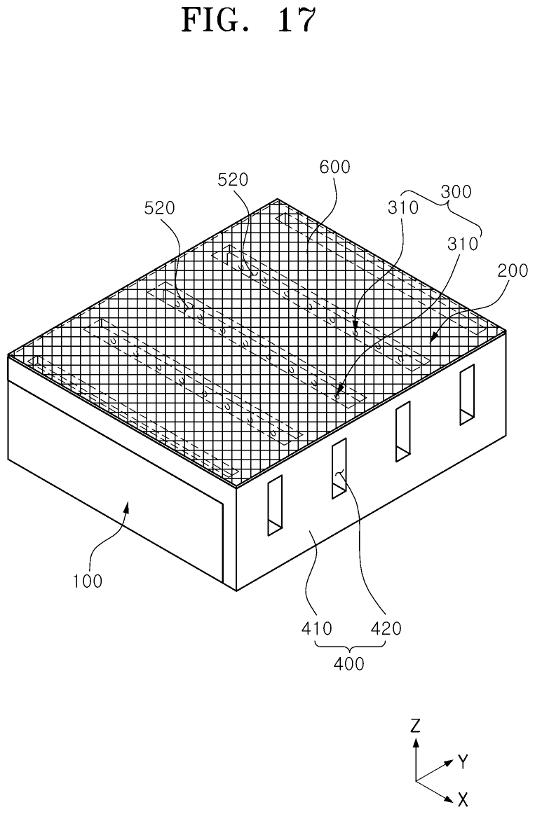

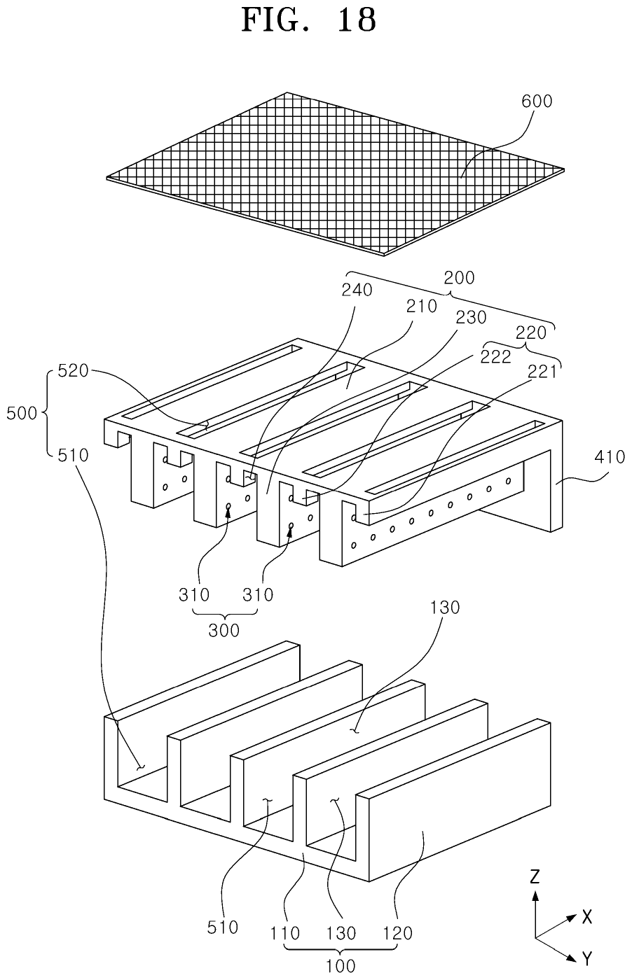

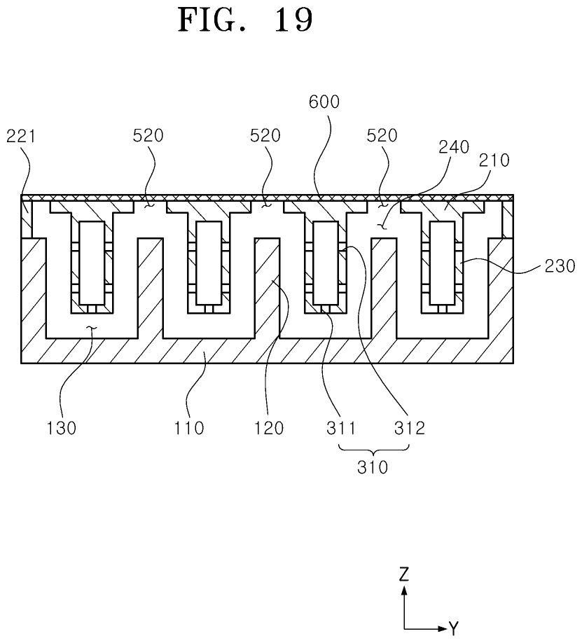

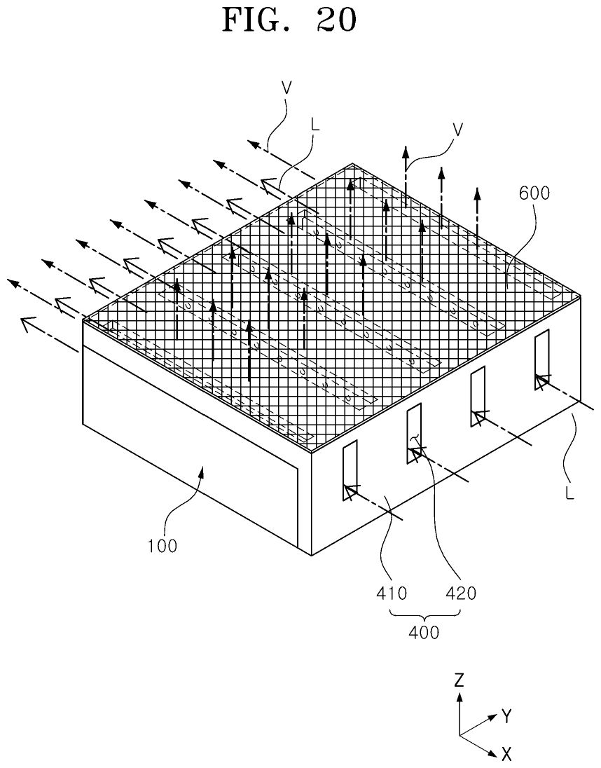

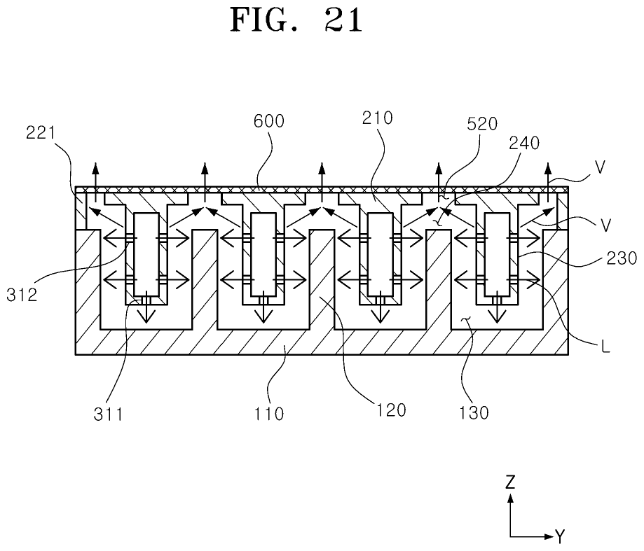

FIG. 17 is a schematic perspective view illustrating a configuration of a heat sink apparatus according to a fourth embodiment of the present disclosure, FIG. 18 is a schematic exploded perspective view illustrating the configuration of the heat sink apparatus according to the fourth embodiment of the present disclosure, FIG. 19 is a schematic front cross-sectional view illustrating the configuration of the heat sink apparatus according to the fourth embodiment of the present disclosure, and FIGS. 20 and 21 are schematic views illustrating a process of operating the heat sink apparatus according to the fourth embodiment of the present the present disclosure.

Referring to FIGS. 17 to 21, the heat sink apparatus according to the fourth embodiment of the present disclosure may include the heating body 100, the supplier 200, the jet ejection part 300, the inlet 400, the outlet 500, and a filter 600.

The heat sink apparatus according to the fourth embodiment of the present disclosure may differ from the heat sink apparatus according to the third embodiment of the present disclosure only in that the heat sink apparatus further includes the filter 600.

Accordingly, in describing the configuration of the heat sink apparatus according to the fourth embodiment of the present disclosure, only the filter 600, which is different from that of the heat sink apparatus according to the third embodiment of the present disclosure, will be described.

The descriptions of the heating body 100, the supplier 200, the jet ejection part 300, the inlet 400, and the outlet 500 according to the third embodiment of the present disclosure may be applied to the heating body 100, the supplier 200, the jet ejection part 300, the inlet 400, and the outlet 500 of the heat sink apparatus according to the fourth embodiment of the present disclosure without change.

The filter 600 is disposed to face the second outlet hole 520 and allows the cooling fluid in vapor phase V generated in the heat exchange channel 130 to be selectively transmitted. Accordingly, the filter 600 may prevent the cooling fluid in liquid phase L from being discharged to the outside of the heat exchange channel 130 through the second outlet hole 520 so that the dryness of the gas inside the heat exchange channel 130 may be maintained at a lower level. Like a hydrophobic membrane, the filter 600 according to the present embodiment may be exemplified as any of various types of gas-liquid separation means that block passing of the cooling fluid in liquid phase L and allow passing of the cooling fluid in vapor phase V among the cooling fluid discharged through the second outlet hole 520. The filter 600 may be formed to have a substantially thin sheet shape and may be seated on an upper surface of the supply body 210. The filter 600 may be integrally coupled to the supply body 210 using an adhesive or the like and may be also detachably coupled to the supply body 210 by bolting, fitting, or the like.

In a heat sink apparatus according to the present disclosure, a supplier that supplies a cooling fluid is made of a material having low thermal conductivity, and an area in direct contact with a heating body is small. Thus, in a process of supplying the cooling fluid to the heating body, the cooling fluid can be prevented from being phase-changed due to heat exchange with the heating body or an external heat source, and a constant temperature of the cooling fluid can be maintained throughout an entire length of a heat exchange channel.

Further, in the heat sink apparatus according to the present disclosure, a jet ejection part can allow the cooling fluid to directly collide with a surface of the heating body so as to prevent a cooling fluid in vapor phase generated by the heat exchange channel from forming a vapor film on the surface of the heating body, thereby increasing heat exchange efficiency and delaying occurrence of a critical heat flux.

Further, in the heat sink apparatus according to the present disclosure, a gas collector collects the cooling fluid in vapor phase generated in the heat exchange channel in a space separate from the heat exchange channel, the collected cooling fluid in vapor phase can be discharged through a second outlet hole and a filter, and thus dryness of a gas in the heat exchange channel can be lowered, and flow stability of the cooling fluid can be further improved.

Although the present disclosure has been described with reference to embodiments illustrated in the drawings, the description is merely illustrative and those skilled in the art to which the technology belongs could understand that various modifications and other equivalent embodiments may be made.

Thus, the true technical scope of the present disclosure should be determined by the appended claims.

What is claimed is:

1. A heat sink apparatus comprising:
a heating body configured to receive heat from an external heat source;
a supplier supported by the heating body and configured to supply a cooling fluid; and
a jet ejection part provided in the supplier and configured to inject the cooling fluid supplied by the supplier toward the heating body.

2. The heat sink apparatus as claimed in claim 1, wherein the heating body comprises:
a first heating body;
a second heating body extending from the first heating body and configured to support the supplier; and
a heat exchange channel disposed adjacent to the second heating body and configured to guide flow of the cooling fluid injected from the jet ejection part.

3. The heat sink apparatus as claimed in claim 2, wherein the second heating body and the heat exchange channel are provided as a plurality of second heating bodies and a plurality of heat exchange channels, and
the second heating bodies and the heat exchange channels are arranged alternately on the first heating body.

4. The heat sink apparatus as claimed in claim 2, wherein the supplier comprises:
a supply body spaced apart from the second heating body;
a support member extending from the supply body and configured to support the supply body with respect to the second heating body; and
a supply channel extending from the support body and disposed inside the heat exchange channel.

5. The heat sink apparatus as claimed in claim 4, wherein a longitudinal direction of the supply channel is parallel to a longitudinal direction of the heat exchange channel.

6. The heat sink apparatus as claimed in claim 4, wherein a cross-sectional area of the supply channel is smaller than a cross-sectional area of the heat exchange channel.

7. The heat sink apparatus as claimed in claim 4, wherein the support member comprises:
a pair of first support members arranged on both sides of the supply body; and
a second support member disposed between the pair of first support members.

8. The heat sink apparatus as claimed in claim 7, wherein a length of the second support member is smaller than a length of the supply channel.

9. The heat sink apparatus as claimed in claim 4, wherein the supplier further comprises a gas collector disposed adjacent to the supply channel and connected to the heat exchange channel.

10. The heat sink apparatus as claimed in claim 9, wherein the gas collector is connected to an upper surface of the heat exchange channel.

11. The heat sink apparatus as claimed in claim 4, wherein the jet ejection part comprises a jet hole formed to pass through the supply channel and configured to inject the cooling fluid to the heat exchange channel.

12. The heat sink apparatus as claimed in claim 11, wherein the jet hole comprises:
a first jet hole disposed to face the first heating body and configured to allow the cooling fluid flowing into the supply channel to collide with the first heating body; and
a second jet hole disposed to face the second heating body and configured to allow the cooling fluid flowing into the supply channel to collide with the second heating body.

13. The heat sink apparatus as claimed in claim 12, wherein the second jet hole passes through the supply channel in a direction inclined at a set angle with respect to a direction perpendicular to the second heating body.

14. The heat sink apparatus as claimed in claim 4, further comprising:
an inlet through which the cooling fluid flows into the supplier; and
an outlet through which the cooling fluid is discharged from the heating body.

15. The heat sink apparatus as claimed in claim 14, wherein the inlet comprises:
an inlet body extending from the supply body and disposed to face one end of the heat exchange channel; and
an inlet hole formed to pass through the inlet body and connected to one end of the supply channel, and
the outlet comprises a first outlet hole spaced apart from the inlet hole and connected to the other end of the heat exchange channel.

16. The heat sink apparatus as claimed in claim 15, wherein the outlet further comprises a second outlet hole formed to pass through the supply body and connected to an upper surface of the heat exchange channel.

17. The heat sink apparatus as claimed in claim 16, further comprising a filter disposed to face the second outlet hole and configured to allow a cooling fluid in vapor phase to be selectively transmitted.

18. The heat sink apparatus of any one as claimed in claim 14, wherein the supplier is made of a material having lower thermal conductivity than the heating body.

19. The heat sink apparatus as claimed in claim 18, wherein the supplier is made of an insulating material.
